(19) United States
(12) Patent Application Publication
(10) Pub. No.: US 2020/0194238 A1
(43) Pub. Date: Jun. 18, 2020

(54) STRUCTURE FOR SUBSTRATE PROCESSING APPARATUS

(71) Applicant: Tokyo Electron Limited, Tokyo (JP)

(72) Inventors: Daisuke ITO, Miyagi (JP); Toshimasa KOBAYASHI, Miyagi (JP); Toshikatsu TOBANA, Miyagi (JP); Takuya OBARA, Miyagi (JP); Yusuke AOKI, Miyagi (JP)

(21) Appl. No.: 16/708,740

(22) Filed: Dec. 10, 2019

(30) Foreign Application Priority Data
Dec. 18, 2018 (JP) 2018-236528

(51) Int. Cl. H01J 37/32

(52) U.S. Cl. CPC H01J 37/32541; H01J 2237/3344; H01J 37/3255

(57) ABSTRACT

A structure for a substrate processing apparatus to be situated opposite a support pedestal for supporting a substrate includes an electrode plate having a surface exposed to an inner space of a chamber, the surface of the electrode plate having a first roughness, and an annular member disposed around the electrode plate and having a surface exposed to the inner space, the surface of the annular member having a second roughness, wherein the first roughness is different from the second roughness.

### BACKGROUND OF THE INVENTION

### 1. Field of the Invention

The disclosures herein relate to a structure for a substrate processing apparatus, and relate to a substrate processing apparatus.

### 2. Description of the Related Art

A substrate processing apparatus is configured as is known in the art to introduce a process gas into a chamber and to apply radio-frequency power to electrodes disposed inside the chamber, thereby applying a desired process such as an etch process to a substrate.

Patent Document 1 discloses a substrate processing apparatus that has an electrode ceiling disk plate having a surface thereof exposed to a processing space.

According to one aspect, the present disclosures provide a substrate processing apparatus and a structure for a substrate processing apparatus that reduce process variation.

### RELATED-ART DOCUMENTS

### [Patent Document]

### [Patent Document 1] Japanese Patent Application Publication No. 2007-123796

### SUMMARY OF THE INVENTION

It is a general object of the present invention to provide a structure for a substrate processing apparatus that substantially obviates one or more problems caused by the limitations and disadvantages of the related art.

According to an aspect, a structure for a substrate processing apparatus to be situated opposite a support pedestal for supporting a substrate includes an electrode plate having a surface exposed to an inner space of a chamber, the surface of the electrode plate having a first roughness, and an annular member disposed around the electrode plate and having a surface exposed to the inner space, the surface of the annular member having a second roughness, wherein the first roughness is different from the second roughness.

According to at least one embodiment, a substrate processing apparatus and a structure for a substrate processing apparatus that reduce process variation are provided.

### BRIEF DESCRIPTION OF THE DRAWINGS

Other objects and further features of the present invention will be apparent from the following detailed description when read in conjunction with the accompanying drawings, in which:

FIG. 1 is a schematic cross-sectional view illustrating an example of a substrate processing apparatus according to the embodiment;

FIG. 2 is a schematic cross-sectional view illustrating an example of a ceiling plate of the substrate processing apparatus according to the embodiment;

FIGS. 3A and 3B are schematic diagrams illustrating relationships between the surface condition of a ceiling electrode plate and a process gas to be consumed.

FIG. 4 is a graph chart illustrating an example of the relationship between the etching rate of a substrate and the time length during which radio-frequency power is applied in the substrate processing device; and

FIGS. 5A and 5B are graph charts in which changes in an etching rate in the case of using the ceiling electrode plate of the embodiment are compared with changes in an etching rate in the case of using a ceiling electrode plate of a comparative example.

### DESCRIPTION OF THE PREFERRED EMBODIMENTS

In the following, embodiments for practicing the present disclosures will be described by referring to the accompanying drawings. In these drawings, the same elements are referred to by the same references, and a description thereof may be omitted.

### <Substrate Processing Apparatus>

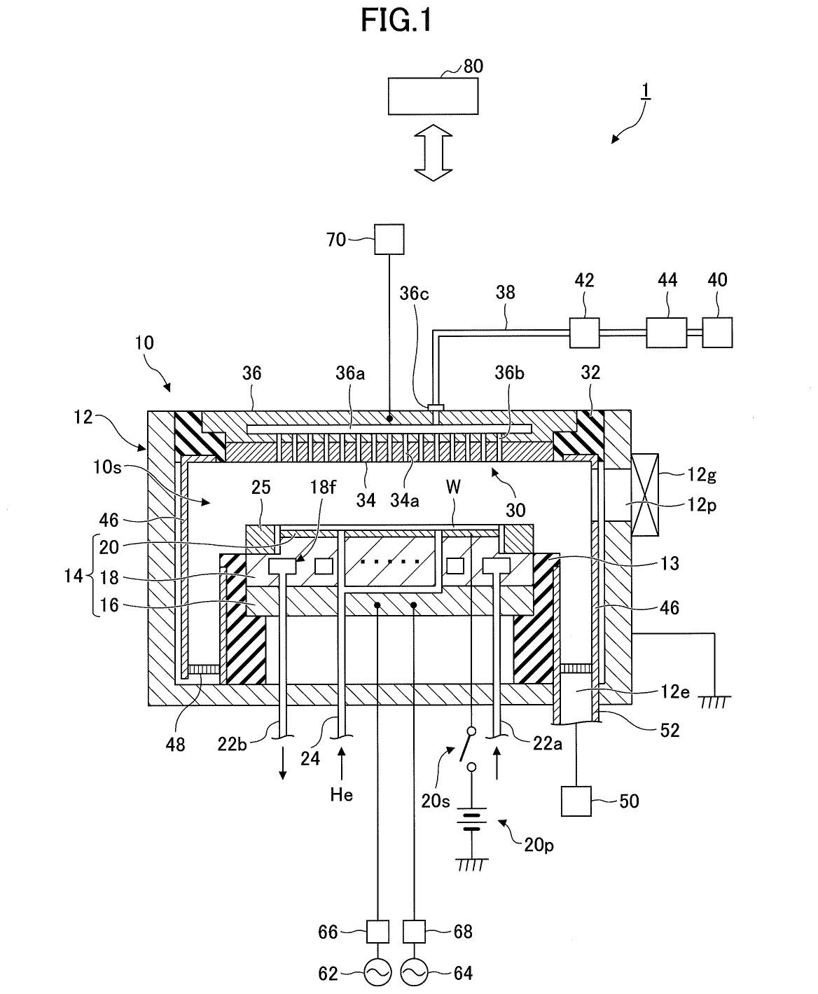

A substrate processing apparatus 1 according to an embodiment will be described with reference to FIG. 1. FIG. 1 is a schematic cross-sectional view illustrating an example of the substrate processing apparatus 1 according to the embodiment.

The substrate processing apparatus 1 includes a chamber 10. The chamber 10 provides an inner space 10s therein. The chamber 10 includes a chamber body 12. The chamber body 12 has a generally cylindrical shape. The chamber body 12 is made of aluminum, for example. An anti-corrosion film is provided on the inner wall of the chamber body 12. The film may be a ceramic such as aluminum oxide, yttrium oxide, or the like.

The chamber body 12 has a pathway 12p formed through the sidewall thereof. A substrate W is transferred between the inner space 10s and the outside of the chamber 10 through the pathway 12p. A gate valve 12g provided along the sidewall of the chamber body 12 is operated to open and close the pathway 12p.

A support 13 is disposed on the bottom of the chamber body 12. The support 13 is made of an insulating material. The support 13 has a generally cylindrical shape. The support 13 extends upward from the bottom of the chamber body 12 inside the inner space 10s. A support pedestal 14 is disposed at the top of the support 13. The support pedestal 14 is configured to support the substrate W in the inner space 10s.

The support pedestal 14 has a lower electrode 18 and an electrostatic chuck 20. The support pedestal 14 may further have an electrode plate 16. The electrode plate 16 is made of a conductive material such as aluminum, and has a generally disk shape. The lower electrode 18 is disposed on the electrode plate 16. The lower electrode 18 is made of a conductive material such as aluminum, and has a generally disk shape. The lower electrode 18 is electrically coupled to the electrode plate 16.

The electrostatic chuck 20 is disposed on the lower electrode 18. The substrate W is placed on the top face of the electrostatic chuck 20. The electrostatic chuck 20 includes a body and one or more electrodes. The body of the electrostatic chuck 20 has a generally disk shape, and is made of a dielectric material. The electrodes of the electrostatic chuck 20 are film electrodes disposed inside the body of the electrostatic chuck 20. The electrodes of the electrostatic chuck 20 are electrically connected to a DC power supply 20p via a switch 20s. Applying a voltage to the electrodes of the electrostatic chuck 20 from the DC power supply 20p causes an electrostatic attractive force to be generated between the electrostatic chuck 20 and the substrate W. The substrate W is held down on the electrostatic chuck 20 by the electrostatic attractive force.

An edge ring 25 is disposed on the perimeter of the lower electrode 18 to surround the edge of the substrate W. The edge ring 25 improves the in-plane uniformity of a plasma process for the substrate W. The edge ring 25 may be made of silicon, silicon carbide, quartz, or the like.

The lower electrode 18 has a flow path 18f disposed therein. A heat exchange medium (e.g., refrigerant) is supplied through a pipe 22a to the flow path 18f from a chiller unit (not shown) provided outside the chamber 10. The heat exchange medium supplied to the flow path 18f is returned to the chiller unit through a pipe 22b. In the substrate processing apparatus 1, the temperature of the substrate W placed on the electrostatic chuck 20 is adjusted by heat exchange between the heat exchange medium and the lower electrode 18.

The substrate processing apparatus 1 has a gas supply line 24. The gas supply line 24 supplies a heat transfer gas (e.g., He gas) from a heat transfer gas supply unit to a gap between the top surface of the electrostatic chuck 20 and the back surface of the substrate W.

The substrate processing apparatus 1 further includes an upper electrode 30. The upper electrode 30 is disposed over the support pedestal 14. The upper electrode 30 is fixed at the upper part of the chamber body 12 through a member 32. The member 32 is made of an insulating material. The upper electrode 30 and the member 32 closes the upper opening of the chamber body 12.

The upper electrode 30 may include a ceiling plate 34 and a support 36. The lower surface of the ceiling plate 34 directly faces the inner space 10s to define the inner space 10s. The ceiling plate 34 may be made of a low resistance conductor or semiconductor with low Joule heat generation. The ceiling plate 34 has a plurality of gas discharge holes 34a extending through the ceiling plate 34 in the thickness direction.

The support 36 supports the ceiling plate 34 in a detachable manner. The support 36 is made of an electrically conductive material such as aluminum. A gas diffusion chamber 36a is provided inside the support 36. The support 36 has a plurality of gas holes 36b extending downwardly from the gas diffusion chamber 36a. The gas holes 36b communicate with the respective gas discharge holes 34a. The support 36 has a gas inlet 36c. The gas inlet 36c is connected to the gas diffusion chamber 36a. A gas supply line 38 is connected to the gas inlet 36c.

A valve group 42, a flow controller group 44, and a gas source group 40 are connected to the gas supply line 38. The gas source group 40, the valve group 42, and the flow controller group 44 constitute a gas supply unit. The gas source group 40 includes a plurality of gas sources. The valve group 42 includes a plurality of open and close valves. The flow controller group 44 includes a plurality of flow controllers. Each of the flow controllers of the flow controller group 44 is a mass flow controller or a pressure-based flow controller. Each of the gas sources of the gas source group 40 is connected to the gas supply line 38 via a corresponding open-and-close valve among the valve group 42 and a corresponding flow controller among the flow controller group 44.

In the substrate processing apparatus 1, a shield 46 is detachably disposed along the inner wall surface of the chamber body 12 and the outer perimeter of the support 13. The shield 46 prevents reaction byproducts from adhering to the chamber body 12. The shield 46 is made by forming an anti-corrosion film on the surface of a base formed of aluminum, for example. The anti-corrosion film may be made of a ceramic such as yttrium oxide.

A baffle plate 48 is disposed between the support 13 and the sidewall of the chamber body 12. The baffle plate 48 is made by forming an anti-corrosion film (e.g., yttrium oxide film) on the surface of a base formed of aluminum, for example. The baffle plate 48 has a plurality of through-holes formed therein. An exhaust port 12e is provided under the baffle plate 48 at the bottom of the chamber body 12. An exhaust device 50 is connected to the exhaust port 12e through an exhaust pipe 52. The exhaust device 50 includes a pressure regulating valve and a vacuum pump such as a turbo-molecular pump.

The substrate processing apparatus 1 includes a first radio-frequency power supply 62 and a second radio-frequency power supply 64. The first radio-frequency power supply 62 is a power supply that generates first radio-frequency power. The first radio-frequency power has a frequency suitable for generating a plasma. The frequency of the first radio-frequency power is in the range of 27 MHz to 100 MHz, for example. The first radio-frequency power supply 62 is connected to the lower electrode 18 via a matching device 66 and the electrode plate 16. The matching device 66 includes a circuit for matching the output impedance of the first radio-frequency power supply 62 with the impedance of the load (at the lower electrode 18). The first radio-frequency power supply 62 may be connected to the upper electrode 30 via the matching device 66. The first radio-frequency power supply 62 is one example of a plasma generator.

The second radio-frequency power supply 64 is a power supply that generates second radio-frequency power. The second radio-frequency power has a frequency lower than the frequency of the first radio-frequency power. When the second radio-frequency power is used in conjunction with the first radio-frequency power, the second radio-frequency power is used as bias radio-frequency power to cause the substrate W to attract ions. The frequency of the second radio-frequency power is in the range of 400 kHz to 13.56 MHz, for example. The second radio-frequency power supply 64 is connected to the lower electrode 18 via a matching device 68 and the electrode plate 16. The matching device 68 includes a circuit for matching the output impedance of the second radio-frequency power supply 64 with the impedance of the load (at the lower electrode 18).

It may be noted that a plasma may be generated using the second radio-frequency power without using the first radio-frequency power, namely, using only a single radio-frequency power. In this case, the frequency of the second radio-frequency power may be greater than 13.56 MHz, and may be 40 MHz, for example. The substrate processing apparatus 1 may include neither the first radio-frequency power supply 62 nor the matching device 66. The second radio-frequency power supply 64 is one example of a plasma generator.

In the substrate processing apparatus 1, gas is supplied from the gas supply unit to the inner space 10s to produce a plasma. Further, the first radio-frequency power and/or the second radio-frequency power are supplied to generate a radio-frequency electric field between the upper electrode 30 and the lower electrode 18. The generated radio-frequency electric field produces a plasma.

The substrate processing apparatus 1 includes a power supply 70. The power supply 70 is connected to the upper electrode 30. The power supply 70 applies a voltage to the upper electrode 30 to cause the ceiling plate 34 to attract positive ions present in the inner space 10s.

The substrate processing apparatus 1 may further include a controller 80. The controller 80 may be a computer that includes a processor, a storage unit such as a memory, an input device, a display device, a signal-input/output interface, and the like. The controller 80 controls the individual parts of the substrate processing apparatus 1. The input device of the controller 80 may be used by an operator to input commands or the like for the purpose of controlling the substrate processing apparatus 1. The display device of the controller 80 may visualize and display the operation status of the substrate processing apparatus 1. Further, control programs and recipe data are stored in the storage unit. The control programs are executed by the processor to cause the substrate processing apparatus 1 to perform various processes. The processor executes the control programs to control the individual parts of the substrate processing apparatus 1 according to the recipe data.

### <Structure for Substrate Processing Apparatus>

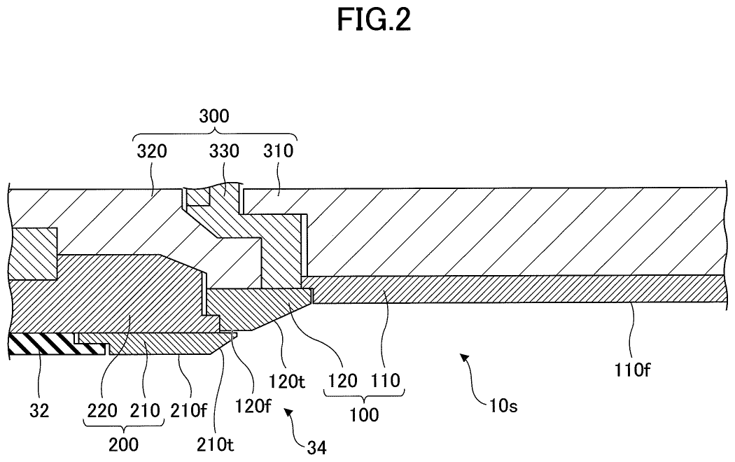

In the following, the structure of the ceiling plate 34 will be described with reference to FIG. 2. FIG. 2 is a schematic cross-sectional view illustrating an example of the ceiling plate 34 of the substrate processing apparatus 1 according to the embodiment.

The ceiling plate 34 includes a ceiling electrode plate 100, a protection ring 200, and a cooling plate 300, and is disposed to face the support pedestal 14 which supports the substrate W. An inner cell 110, an outer cell 120, and a first protection ring 210, which are made of a silicon-containing compound such as quartz and are exposed to the inner space 10s, are referred to as a structure for a substrate processing apparatus.

The ceiling electrode plate 100 includes the inner cell 110 and the outer cell 120. The inner cell 110, which is a disk-shaped member made of a silicon-containing compound such as quartz, is disposed over the support pedestal 14 (see FIG. 1). The inner cell 110 receives a voltage applied by the power supply 70 (see FIG. 1) to serves as the first upper electrode part. The inner cell 110 has a flat face 110f exposed to the inner space 10s. The outer cell 120, which is a ring-shaped member made of a silicon-containing compound such as quartz, is disposed on the outer periphery of the inner cell 110. The outer cell 120 receives a voltage applied by the power supply 70 (see FIG. 1) to serves as the second upper electrode part. The outer cell 120 has a flat face 120f and a tapered face 120t that are exposed to the inner space 10s. The power supply 70 (see FIG. 1) is configured to apply a voltage individually to the inner cell 110 and to the outer cell 120. With this arrangement, a voltage distribution on the ceiling electrode plate 100 (i.e., on the ceiling plate 34) may be adjusted. Further, the surface (i.e., the flat faces 110f and 120f as well as the tapered face 120t) of the ceiling electrode plate 100 exposed to the inner space 10s is adjusted to a predetermined first roughness.

The protection ring 200, which is a ring-shaped member made of a silicon-containing compound such as quartz, is disposed on the outer periphery of the outer cell 120. In other words, the protection ring 200 serves to keep the member 32 made of an insulating material away from the support pedestal 14. This arrangement prevents particles generated from the member 32 from affecting processes performed on the substrate W placed on the support pedestal 14. The protection ring 200 includes the first protection ring 210 and a second protection ring 220. The first protection ring 210, which is a component exposed to the inner space 10s, is replaced during maintenance, for example. The second protection ring 220, which is a component that is not exposed to the inner space 10s, may be made thicker than the first protection ring 210, and is reused after maintenance. The first protection ring 210 has a flat face 210f and a tapered face 210t that are exposed to the inner space 10s. Further, the surface (i.e., the flat face 210f and the tapered face 210t) of the protection ring 200 exposed to the inner space 10s is adjusted to a predetermined second roughness.

The cooling plate 300 is interposed between the support 36 (see FIG. 1) and the ceiling electrode plate 100 (i.e., the inner cell 110 and the outer cell 120) to cool the ceiling electrode plate 100 to a predetermined temperature during the plasma process.

The cooling plate 300 includes a first member 310 in contact with the inner cell 110, a second member 320 in contact with the outer cell 120, and a third member 330 separating the first member 310 from the second member 320.

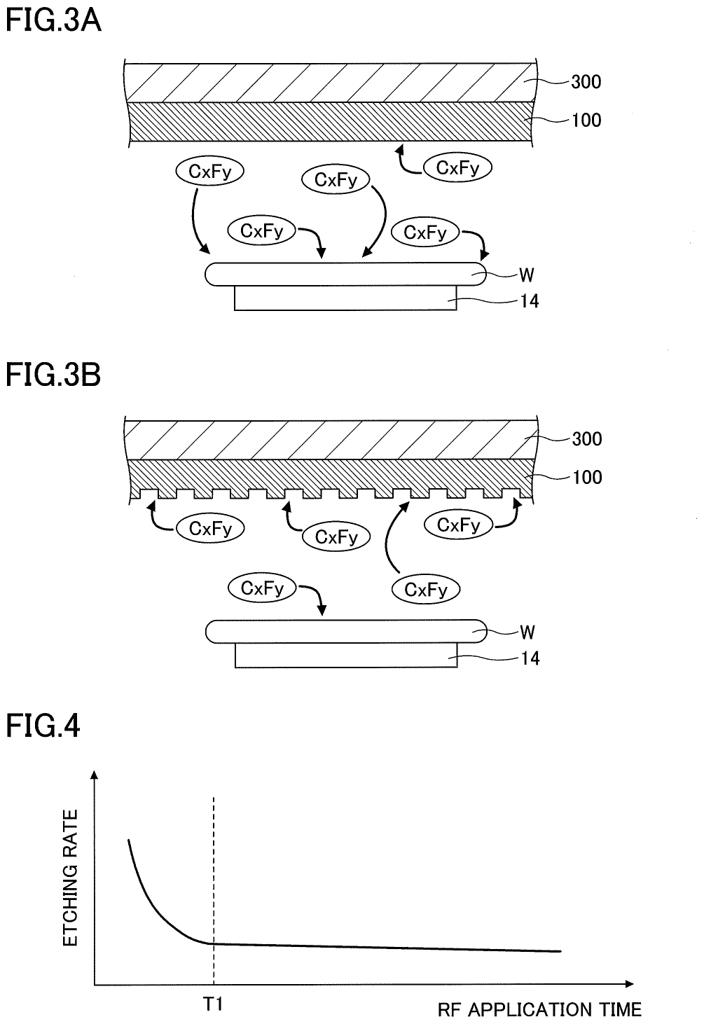

In the following, the relationship between the condition of the surface of the ceiling electrode plate 100 exposed to the inner space 10s and the etching rate of the substrate W will be described with reference to FIG. 3. FIGS. 3A and 3B are schematic diagrams illustrating the relationship between the surface condition of the ceiling electrode plate 100 and a process gas to be consumed. FIG. 3A illustrates a condition in which the surface roughness of the ceiling electrode plate 100 is low (e.g., arithmetic mean roughness Ra=0.02). (In the present disclosures, the unit of surface roughness is micrometers.) FIG. 3B illustrates a condition in which the surface roughness of the ceiling electrode plate 100 is high (e.g., arithmetic mean roughness Ra=7.0). Further, an example will be described in which a CF-based gas (denoted as CxFy in FIG. 3) is used as a process gas to etch the substrate W.

In the condition illustrated in FIG. 3A, the surface area of the ceiling electrode plate 100 is smaller than in the case illustrated in FIG. 3B which will be described later. Because of this, the process gas consumed on the surface of the ceiling electrode plate 100 is less in amount than in the case illustrated in FIG. 3B. As a result, the process gas consumed on the substrate W is greater in amount than in the case illustrated in FIG. 3B. The etching rate of the substrate W is thus higher than in the case illustrated in FIG. 3B.

In the condition illustrated in FIG. 3B, the surface area of the ceiling electrode plate 100 is larger than in the case illustrated in FIG. 3A. Because of this, the process gas consumed on the surface of the ceiling electrode plate 100 is greater in amount than in the case illustrated in FIG. 3A. As a result, the process gas consumed on the substrate W is less in amount than in the case illustrated in FIG. 3A. The etching rate of the substrate W is thus lower than in the case illustrated in FIG. 3A.

FIG. 4 is a graph chart illustrating an example of the relationship between the etching rate of the substrate. W and the time length (i.e., RF application time) during which the first radio-frequency power is applied in the substrate processing apparatus 1. In this example, the substrate W is etched by the substrate processing apparatus 1 using a ceiling electrode plate having a low surface roughness (e.g., arithmetic mean roughness Ra=0.02).

As illustrated in FIG. 3, the etching rate of the substrate W is high when the surface roughness of the ceiling electrode plate is low With the passage of the RF application time in the substrate processing apparatus 1, the surface of the ceiling electrode plate 100 continues to be etched by the process gas, which results in the surface roughness of the ceiling electrode plate 100 being changed. As illustrated in FIG. 4, thus, the etching rate significantly changes before the RF application time reaches T1 in the substrate processing apparatus 1. After the RF application time reaches T1 in the substrate processing apparatus 1, changes in the surface roughness of the ceiling electrode plate 100 are relatively small despite the fact that the surface of the ceiling electrode plate 100 continues to be etched by the process gas, which results in stabilization of the etching rate.

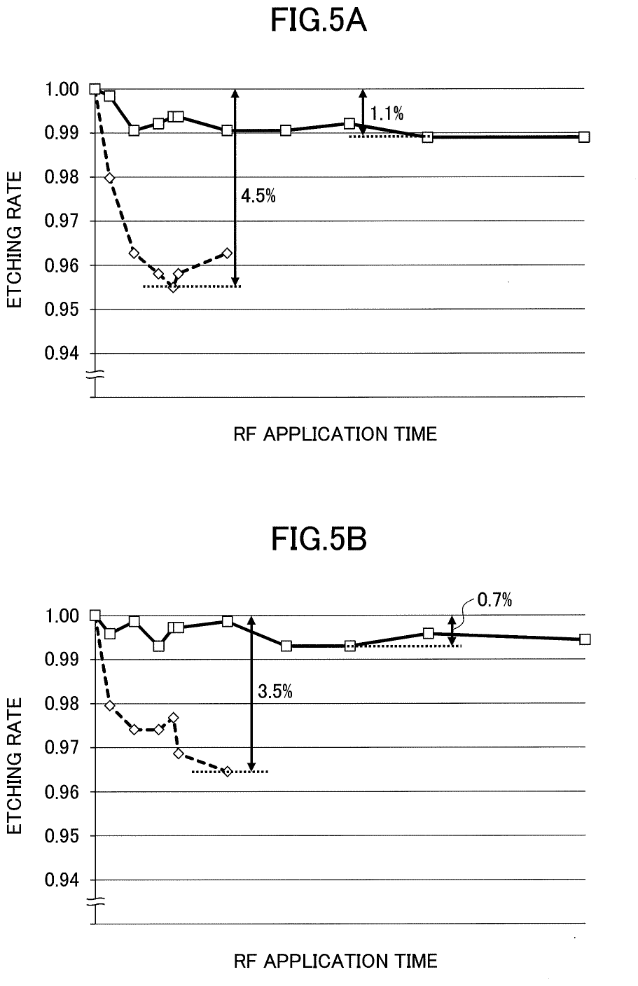

FIGS. 5A and 5B are drawings illustrating the results of experiments. FIGS. 5A and 5B are graph charts in which changes in an etching rate in the case of using the ceiling electrode plate 100 of the embodiment are compared with changes in an etching rate in the case of using a ceiling electrode plate of a comparative example. In the graph charts of FIGS. 5A and 5B, the horizontal axis represents the RF application time, and the vertical axis represents the etching rage. It should be noted that numerical values on the vertical axis are normalized such that the etching rate at the initial state is set to 1. Solid lines indicate the etching rate in the case of using the ceiling electrode plate 100 of the embodiment, and dashed lines indicate the etching rate in the case of using the ceiling electrode plate of the comparative example. FIG. 5A illustrates a case in which a silicon oxide film of a substrate W is etched, and FIG. 5B illustrates a case in which a silicon nitride film of a substrate W is etched.

In the comparative example, a ceiling electrode plate with a low surface roughness (Ra=0.02) was used. In the embodiment, the ceiling electrode plate 100 with the surface roughness falling within a predetermined range of roughness (from Ra=4.5 to Ra=8.0) was used.

As shown in FIG. 5A, in the case of etching a silicon oxide film, the etching rate in the comparative example showed a change of 4.5%. In contrast, the etching rate in the embodiment showed a change of 1.1%.

As shown in FIG. 5B, in the case of etching a silicon nitride film, the etching rate in the comparative example showed a change of 3.5%. In contrast, the etching rate in the embodiment showed a change of 0.7%.

As was described above, with the use of the ceiling electrode plate 100 of the embodiment, changes in the etching rate are reduced with respect to both the etching of a silicon oxide film and the etching of a silicon nitride film, compared with the use of the ceiling electrode plate of the comparative example.

The structure for the substrate processing apparatus used in the substrate processing apparatus 1 of the embodiment is configured such that the roughness of the surface of the ceiling electrode plate 100 (i.e., the inner cell 110 and outer cell 120) exposed to the inner space 10s differs from roughness of the surface of the first protection ring 210 exposed to the inner space 10s.

Further, the roughness of the surface of the ceiling electrode plate 100 exposed to the inner space 10s is preferably greater than the roughness of the surface of the first protection ring 210 exposed to the inner space 10s. With this arrangement in which the ceiling electrode plate 100 has a high surface roughness, changes in the etching rate is reduced. Further, the use of the first protection ring 210 having a low surface roughness serves to reduce the consumption of the process gas by the first protection ring 210, thereby reducing the lowering of the etching rate of the substrate W.

The arithmetic mean roughness Ra of the surface of the ceiling electrode plate 100 exposed to the inner space 10s is preferably greater than or equal to 4.5 and less than or equal to 8.0. Alternatively, the maximum height Rz is preferably greater than or equal to 25.0 and less than or equal to 50.0. When the arithmetic mean roughness Ra is less than 4.5 or the maximum height Rz is less than 25.0, the surface roughness of the ceiling electrode plate 100 changes through etching of the ceiling electrode plate 100, which results in changes in the etching rate. When the arithmetic mean roughness Ra is greater than 8.0 or the maximum height Rz is greater than 50.0, the ceiling electrode plate 100 has a large surface area, which reduces process-gas consumption by the substrate W, thereby lowering the etching rate of the substrate W. With the surface of the ceiling electrode plate 100 having an arithmetic mean roughness Ra of 4.5 or more and 8.0 or less, or having a maximum height Rz of 25.0 or more and 50.0 or less, changes in the etching rate are reduced while securing a proper etching rate for the substrate W. It may be noted that surface treatment with an abrasives agent (e.g., sand blasting) may be used to provide a desired roughness to the ceiling electrode plate 100.

Similarly, the arithmetic mean roughness Ra of the surface of the first protection ring 210 exposed to the inner space 10s is preferably greater than or equal to 1.0 and less than or equal to 2.5. Alternatively, the maximum height Rz is preferably greater than or equal to 10.0 and less than or equal to 15.0. When the arithmetic mean roughness Ra is less than 1.0, or the maximum height Rz is less than 10.0, the fabrication cost increases. When the arithmetic mean roughness Ra is greater than 2.5 or the maximum height Rz is greater than 15.0, the first protection ring 210 has a large surface area, which reduces process-gas consumption by the substrate W, thereby lowering the etching rate of the substrate W. Setting the arithmetic mean roughness Ra of the surface of the first protection ring 210 to 1.0 or more and 2.5 or less, or setting the maximum height Rz to 10.0 or more and 15.0 or less, ensures a proper etching rate for the substrate. It may be noted that surface treatment with abrasives grains (e.g., grinding with grains) may be used to provide a desired roughness to the first protection ring 210.

Moreover, the roughness of the tapered face 120t of the ceiling electrode plate 100 is preferably greater than the roughness of the flat faces 110f and 120f of the ceiling electrode plate 100. With this arrangement, the fabrication cost of the ceiling electrode plate 100 may be reduced.

Although the embodiments of the substrate processing apparatus 1 have been described, the present disclosures are not limited to these embodiments, but various variations and modifications may be made without departing from the scope of the present disclosures as set forth in the claims.

Although the ceiling electrode plate 100 has heretofore been described with respect to an example in which the ceiling electrode plate 100 is constituted by the inner cell 110 and the outer cell 120, this example is not intended to be limiting. The ceiling electrode plate 100 may be constituted by one member, or may be constituted by three or more members. The surface roughness of the inner cell 110 and the surface roughness of the outer cell 120 may be different from each other. Making the surface roughness of the inner cell 110 and the surface roughness of the outer cell 120 different from each other allows an etching rate to be adjusted in the radial direction of the substrate W.

The process gas is not limited to a CF-based gas, and another process gas may alternatively be used.

The process gas may also include a noble gas such as argon, helium, krypton, xenon, or the like. A noble gas fed into the inner space 10s becomes a plasma through dissociation and ionization, mainly due to the first radio-frequency power. The plasma contains noble gas ions. The noble gas ions move toward the ceiling electrode plate 100 due to the voltage applied by the power supply 70 to impact on the ceiling electrode plate 100, thereby sputtering the silicon of the ceiling electrode plate 100. As a result, the roughness of the surface of the ceiling electrode plate 100 changes due to etching and sputtering, and the roughness of the surface of the first protection ring 210 changes due to etching. In consideration of this, the surface of the ceiling electrode plate 100 may be roughened to a first roughness in accordance with changes in roughness caused by etching and sputtering, and the surface of the first protection ring 210 may be roughened to a second roughness different from the first roughness in accordance with changes in roughness caused by etching, thereby reducing changes in the etching rate of the substrate W.

Further, although the roughness of the surface of the ceiling electrode plate 100 exposed to the inner space 10s has been described as being greater than the roughness of the surface of the first protection ring 210 exposed to the inner space 10s, this is not intended to be limiting. The roughness of the surface of the ceiling electrode plate 100 exposed to the inner space 10s may be made smaller than the roughness of the surface of the first protection ring 210 exposed to the inner space 10s. Changing the roughness of the surface of the first protection ring 210 allows an etching rate to be changed with respect to the perimeter area of the substrate W.

The present application is based on and claims priority to Japanese patent application No. 2018-236528 filed on Dec. 18, 2018, with the Japanese Patent Office, the entire contents of which are hereby incorporated by reference.

What is claimed is:

1. A structure for a substrate processing apparatus to be situated opposite a support pedestal for supporting a substrate, comprising:
an electrode plate having a surface exposed to an inner space of a chamber, the surface of the electrode plate having a first roughness; and
an annular member disposed around the electrode plate and having a surface exposed to the inner space, the surface of the annular member having a second roughness,
wherein the first roughness is different from the second roughness.

2. The structure as claimed in claim 1, wherein the first roughness is greater than the second roughness.

3. The structure as claimed in claim 1, wherein the surface of the electrode plate exposed to the inner space includes a flat face and a tapered face, and
wherein within a range of the first roughness, a roughness of the tapered face is greater than a roughness of the flat face.

4. The structure as claimed in claim 3, wherein the electrode plate is divided into a first electrode plate having the flat face exposed to the inner space and a second electrode plate having the tapered face exposed to the inner space, the second electrode plate being situated around the first electrode plate.

5. The structure as claimed in claim 1, wherein the first roughness is defined by an arithmetic mean roughness Ra that is greater than or equal to 4.5 and less than or equal to 8.0.

6. The structure as claimed in claim 1, wherein the first roughness is defined by a maximum height Rz that is greater than or equal to 25.0 and less than or equal to 50.0.

7. The structure as claimed in claim 1, wherein the second roughness is defined by an arithmetic mean roughness Ra that is greater than or equal to 1.0 and less than or equal to 2.5.

8. The structure as claimed in claim 1, wherein the second roughness is defined by a maximum height Rz that is greater than or equal to 10.0 and less than or equal to 15.0.

9. The structure as claimed in claim 1, wherein the electrode plate and the annular member are made of a compound containing silicon.

10. The structure as claimed in claim 9, wherein the electrode plate and the annular member are made of quartz.

11. A substrate processing apparatus comprising the structure of claim 1.
